(19) United States
(12) Patent Application Publication
(10) Pub. No.: US 2026/0255505 A1
(43) Pub. Date: Aug. 27, 2026

(54) ELECTRONIC CONTROL DEVICE

(71) Applicant: ASTEMO, LTD., Tokyo (JP)

(72) Inventor: Kiyoshi Ohmori, Hitachinaka-shi, Ibaraki (JP)

(21) Appl. No.: 19/160,985

(22) PCT Filed: May 12, 2023
(86) PCT No.: PCT/JP2023/017862

§ 371 Date: Aug. 29, 2025

(51) Int. Cl. H05K 5/00; H05K 5/02; H05K 5/03

(52) U.S. Cl. CPC H05K 5/006; H05K 5/0052; H05K 5/0069; H05K 5/0247; H05K 5/03

(57) ABSTRACT

An electronic control device (10) includes: a case (20) which is open at one end and closed at the other end; a circuit board (12) which is accommodated inside the case (20) and on which electronic components are mountable; and a cover (40) which closes the opening of the case (20). A bottom portion (25) located at the other end of the case (20) is provided with a first V-shaped holding portion (33) which extends toward an edge of the circuit board (12), has a substantially V-shape, and holds the edge of the circuit board (12) from both sides. The cover (40) is provided with a second V-shaped holding portion (43) which extends toward the edge of the circuit board (12), has a substantially V-shape, and holds the edge of the circuit board (12) from both sides.

### TECHNICAL FIELD

The present invention relates to an electronic control device.

### BACKGROUND ART

Many vehicles are equipped with an electronic control device called an ECU (Electronic Control Unit). A conventional technique relating to the electronic control device is disclosed in Patent Document 1.

The electronic control device shown in Patent Document 1 includes a case which is open at one end and closed at the other end, a circuit board which is accommodated inside the case and on which electronic components are mountable, and a cover which closes an opening of the case.

This electronic control device has the case or cover provided with a protrusion having a sloped surface, and the circuit board is held by being bent in the thickness direction. Accordingly, the circuit board is prevented from rattling inside the case.

### CITATION LIST

### Patent Document

Patent Document 1: Japanese Unexamined Patent Publication No. H9-74291

### DISCLOSURE OF THE INVENTION

### Problem to be Solved by the Invention

According to the electronic control device disclosed in Patent Document 1, distortion occurs in the bent portion of the circuit board. Since a large load is applied to a portion where distortion occurs, it is preferable not to mount electronic components in such portions. As a result, the space available for mounting electronic components becomes smaller. In order to secure the necessary mounting space, the electronic control device becomes larger.

An object of the present invention is to provide a compact electronic control device.

### Means for Solving Problem

Hereinafter, the present disclosure will be described.

According to the present disclosure, provided is an electronic control device including: a case which is open at one end and closed at the other end; a circuit board which is accommodated inside the case and on which electronic components are mountable; and a cover which closes an opening of the case, wherein a bottom portion located at the other end of the case is provided with a first V-shaped holding portion which extends toward an edge of the circuit board, has a substantially V-shape, and holds the edge of the circuit board from both sides, wherein the cover is provided with a second V-shaped holding portion which extends toward the edge of the circuit board, has a substantially V-shape, and holds the edge of the circuit board from both sides, and wherein the circuit board is sandwiched between the first V-shaped holding portion and the second V-shaped holding portion.

### Effect of the Invention

According to the present invention, it is possible to provide a compact electronic control device.

### BRIEF DESCRIPTION OF DRAWINGS

FIG. 1 is a perspective view of an electronic control device according to a first embodiment;

FIG. 2 is an exploded perspective view of the electronic control device shown in FIG. 1;

FIG. 3 is a cross-sectional view showing the electronic control device shown in FIG. 1 in plan view;

FIG. 4 is a cross-sectional view taken along the line 4-4 of FIG. 3;

FIG. 5 is a view seen from the arrow 5 in FIG. 2;

FIG. 6 is a diagram illustrating a step of inserting a circuit board into a case;

FIG. 7 is a diagram illustrating a step of fixing a cover to the case;

FIG. 8A is an exploded cross-sectional view showing an electronic control device according to a second embodiment in plan view;

FIG. 8B is a cross-sectional view of an assembled state of the electronic control device shown in FIG. 8A;

FIG. 9 is a cross-sectional view of an electronic control device according to a third embodiment in side view;

FIG. 10 is a cross-sectional view of an electronic control device according to a fourth embodiment in side view;

FIG. 11 is a perspective view of a cover used in an electronic control device according to a fifth embodiment;

FIG. 12 is a perspective view of a cover used in an electronic control device according to a sixth embodiment; and

FIG. 13 is a cross-sectional view of an electronic control device according to a seventh embodiment in plan view.

### BEST MODE(S) FOR CARRYING OUT THE INVENTION

Embodiments of the present invention will be described below with reference to the attached drawings. Furthermore, the embodiments shown in the attached drawings are merely examples of the present invention, and the present invention is not limited to these embodiments.

### First Embodiment

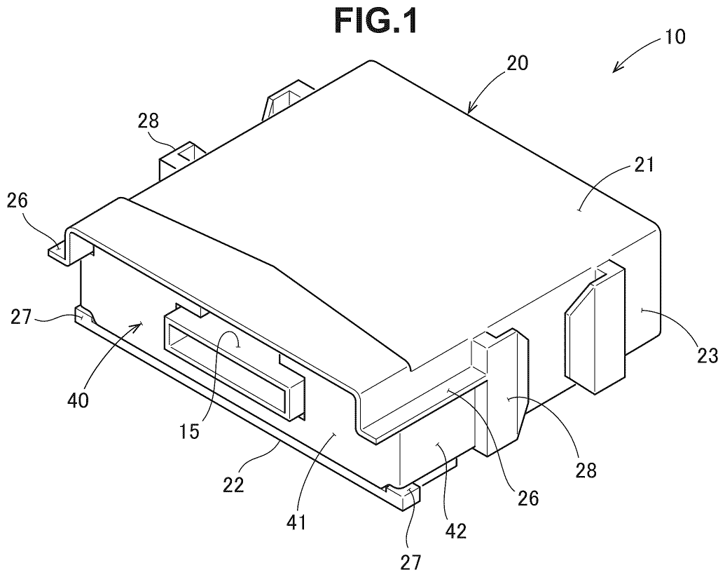

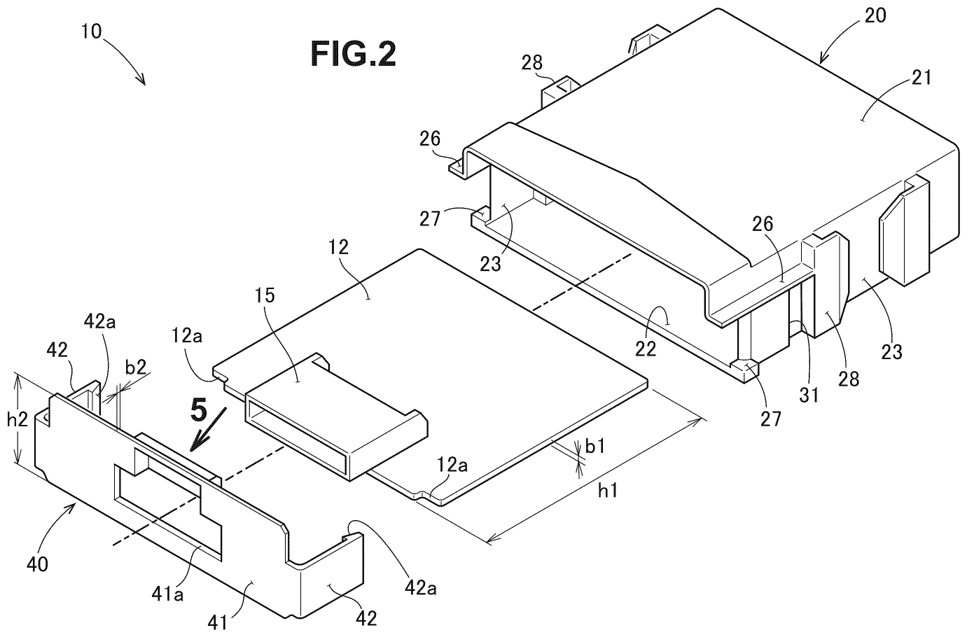

FIGS. 1 and 2 will be used for reference. An electronic control device 10 includes a case 20 which is open at one end and closed at the other end, a circuit board 12 which is accommodated inside the case 20 and on which electronic components are mountable, and a cover 40 which closes the opening of the case 20.

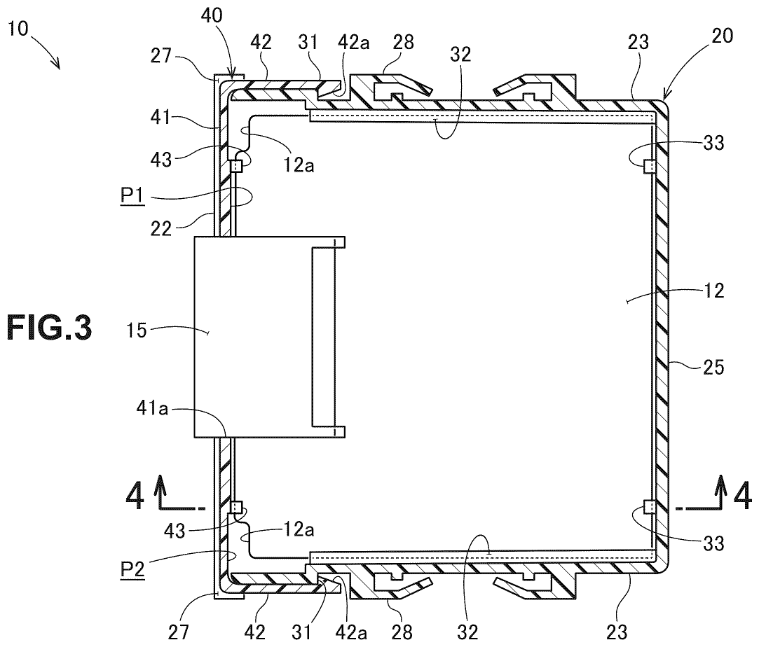

FIGS. 2 and 3 will be used for reference. The case 20 is made of a resin such as polybutylene terephthalate, polyamide, or polyphenylene sulfide.

The case 20 has a case upper surface portion 21 which covers the circuit board 12 from above and has a substantially rectangular shape, a case lower surface portion 22 which faces the case upper surface portion 21 and covers the circuit board 12 from below, a case side surface portion 23 which connects the case upper surface portion 21 and the case lower surface portion 22 and covers each side of the circuit board 12, and a bottom portion 25 which is formed in a rectangular cylindrical shape and closes the other ends of the case upper surface portion 21, the case lower surface portion 22, and the case side surface portion 23.

The case 20 has a flat shape in which the height of the case side surface portion 23 is smaller than the width of the case upper surface portion 21 and the case lower surface portion 22.

The case 20 has an upper guide portion 26 which is formed on the outside of the case side surface portion 23 and protrudes along the upper surface of the cover 40 to be a guide when attaching the cover 40, a lower positioning portion 27 which is formed at the lower portion of the other end of the case side surface portion 23 and positions the lower surface of the cover 40, and an attachment portion 28 which attaches the case 20 to the other components.

Further, the case 20 has a locked portion 31 which is formed in a step shape in the case side surface portion 23 and is locked with the cover 40 and a guide rail portion 32 which is formed on the inner surface in a rail shape to serve as a guide when inserting the circuit board 12.

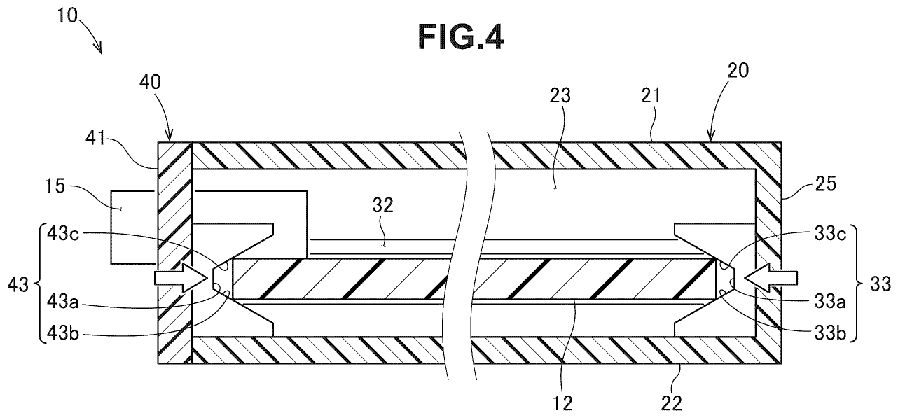

FIG. 4 will be used for reference. The case 20 has a first V-shaped holding portion 33 which extends toward the edge of the circuit board 12, has a substantially V-shape, and holds the edge of the circuit board 12 from both sides. As shown in FIG. 3, the first V-shaped holding portion 33 is provided at two positions to match both ends of the circuit board 12.

FIG. 1 will be used for reference. One end of the case upper surface portion 21 covers the upper side of the cover 40 and restricts the upward displacement of the cover 40.

One end of the case lower surface portion 22 covers the lower side of the cover 40 and restricts the downward displacement of the cover 40.

The end of the upper guide portion 26 formed in the case side surface portion 23 is connected to the attachment portion 28. The upper guide portion 26, the lower positioning portion 7, and the attachment portion 28 are formed on each of the left and right case side surface portions 23.

FIG. 4 will be used for reference. The first V-shaped holding portion 33 has a first bottom portion 33a which corresponds to the V-shaped bottom and is thinner than the thickness of the circuit board 12, a first lower tapered portion 33b which extends obliquely downward from the lower end of the first bottom portion 33a, and a first upper tapered portion 33c which extends obliquely upward from the upper end of the first bottom portion 33a. The inclination angles of the first lower tapered portion 33b and the first upper tapered portion 33c with respect to the first bottom portion 33a are approximately the same. Furthermore, the first lower tapered portion 33b and the first upper tapered portion 33c may be formed in a curved surface.

For the circuit board 12, it is preferable to use, for example, a hard board called a rigid board. As an example, a printed circuit board in which wiring is printed on both sides of a glass epoxy board can be used. On the circuit board 12, electronic components such as ICs and capacitors are mounted.

The corner on the other end side (the end close to the cover 40) of the circuit board 12 may be formed as a recessed portion 12a. By forming the recessed portion 12a, it is possible to prevent the cover 40 from contacting the corner of the circuit board 12 even when the cover 40 is significantly bent.

Furthermore, the circuit board 12 may be any type of board, such as a single-sided board or a multi-layer board, but is not limited to these.

A connector 15 to which a harness can be connected is attached to the upper surface of the circuit board 12. The connector 15 is made of a resin such as polybutylene terephthalate, polyamide, or polyphenylene sulfide. Further, the connector 15 has a plurality of connector terminals made of a metal whose main component is copper. The connector terminals are used to transmit and receive voltage and current between the inside and outside of the electronic control device 10, and are connected to the circuit board 12 by soldering, press-fitting, or the like.

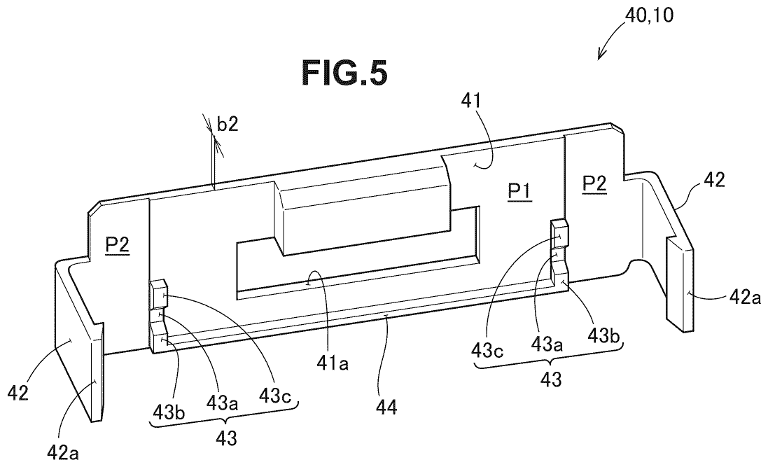

FIG. 5 will be used for reference. The cover 40 is made of a resin such as polybutylene terephthalate, polyamide, or polyphenylene sulfide.

The cover 40 has a substantially rectangular cover body 41 which closes the opening of the case 20, a fixing portion 42 which extends from the cover body 41 along the case side surface portion 23 and is fixed to the case 20, and a second V-shaped holding portion 43 which extends from the cover body 41 toward the edge of the circuit board 12, has a substantially V-shape, and holds the edge of the circuit board 12 from both sides.

The cover body 41 has a substantially rectangular plate shape and is provided with a connector through-hole 41a at the center through which the connector 15 (see FIG. 3) passes. The plate thickness of the cover body 41 is thicker at a portion P1 between one second V-shaped holding portion 43 and the other second V-shaped holding portion 43 than at a portion P2 other than this portion.

FIG. 2 will be used for reference. Further, the bending rigidity of the cover 40 is lower than the bending rigidity of the circuit board 12. More specifically, the bending rigidity of the circuit board 12 can be calculated by multiplying the Young's modulus E1 of the material by the second moment of area I1. Here, when the thickness of the circuit board 12 is b1 and the length is h1, I1 is expressed as I1=(b1×h1\hat{ }3)/12. In other words, the bending rigidity of the circuit board 12 is expressed by E1×(b1×h1\hat{ }3)/12. Similarly, the bending rigidity of the cover 40 is expressed as E2×(b2×h2\hat{ }3)/12, where E2 is the Young's modulus of the material, b2 is the thickness of the thick portion P1 (see FIG. 5), and h2 is the height. In order for the bending rigidity of the cover 40 to be lower than the bending rigidity of the circuit board 12, it is sufficient that the relationship E1×(b1×h1\hat{ }3)>E2×(b2×h2\hat{ }3) is satisfied.

FIG. 3 will be used for reference. The fixing portions 42 extend from the left and right ends of the circuit board 12 along the case side surface portions 23. The tip of the fixing portion 42 is a substantially triangular claw-shaped locking claw portion 42a that is locked to the locked portion 31.

FIG. 4 will be used for reference. Each second V-shaped holding portion 43 is formed at a position facing the first V-shaped holding portion 33. The second V-shaped holding portion 43 has a second bottom portion 43a which corresponds to the V-shaped bottom and is thinner than the thickness of the circuit board 12, a second lower tapered portion 43b which extends obliquely downward from the lower end of the second bottom portion 43a, and a second upper tapered portion 43c which extends obliquely upward from the upper end of the second bottom portion 43a. The inclination angles of the second lower tapered portion 43b and the second upper tapered portion 43c with respect to the second bottom portion 43a are approximately the same. Further, the inclination angle of the second lower tapered portion 43b with respect to the second bottom portion 43a is substantially the same as the inclination angle of the first lower tapered portion 33b with respect to the first bottom portion 33a. Furthermore, the second lower tapered portion 43b and the second upper tapered portion 43c may be formed in a curved shape.

FIG. 5 will be used for reference. The lower ends of two second lower tapered portions 43b are connected to each other by a holding portion connection portion 44. The holding portion connection portion 44 is integrally formed with the cover body 41.

Furthermore, the holding portion connection portion 44 does not necessarily need to be connected to the two second lower tapered portions 43b, and may be unnecessary if the cover body 41 has sufficient rigidity.

In addition, the holding portion connection portion 44 can be formed to connect two first V-shaped holding portions 33 (see FIG. 3).

A method of assembling the electronic control device 10 described above will be described.

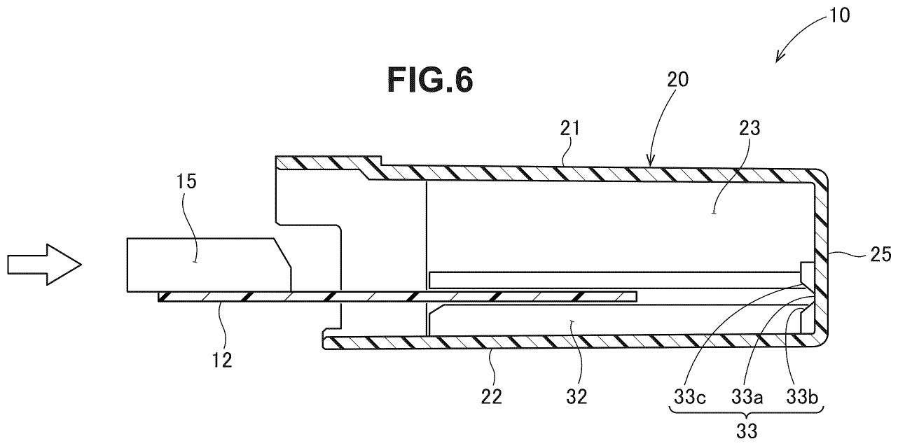

FIG. 6 will be used for reference. First, the circuit board 12 is inserted into the case 20 from the end opposite to the end to which the connector 15 is attached. When inserting the circuit board into the case 20, the circuit board 12 is inserted along the guide rail portion 32. The circuit board 12 is inserted until the edge of the circuit board 12 comes into contact with the first V-shaped holding portion 33.

Furthermore, when inserting the circuit board, it is not necessary to insert the circuit board along the guide rails, and the width size of the circuit board can be freely set according to the scale of the electronic circuit.

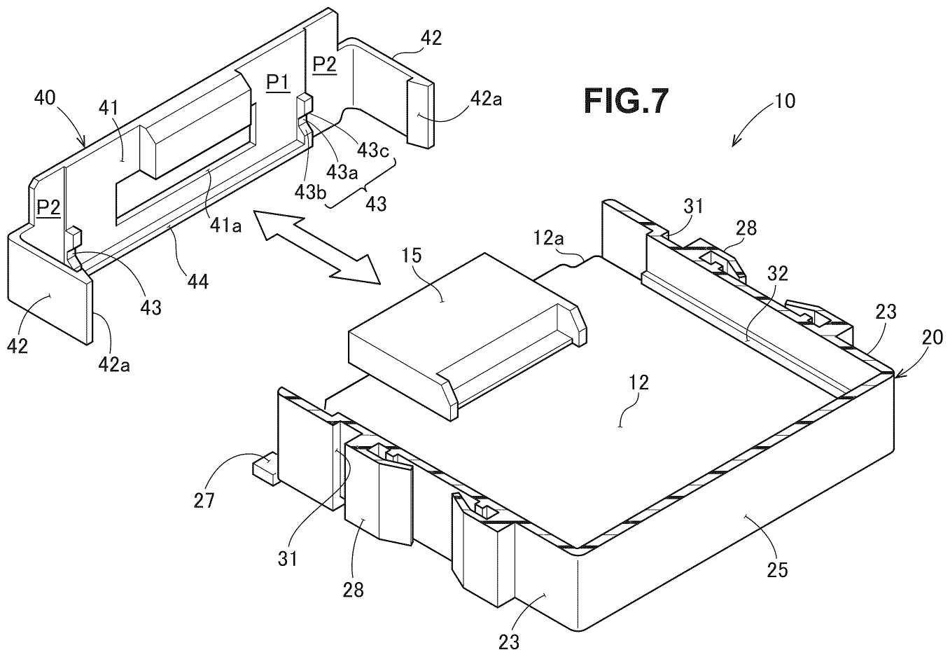

FIG. 7 will be used for reference. Next, the cover 40 is pressed toward the case 20 so that the cover 40 is attached to the case 20. When attaching the cover 40 to the case 20, the fixing portion 42 is inserted between the upper guide portion 26 and the lower positioning portion 27, and the locking claw portion 42a is pressed in a bent state. By pressing the cover 40 to a position in which the locking claw portion 42a comes into contact with the locked portion 31, the cover 40 is attached to the case 20. When attaching the cover 40 to the case 20, the edge of the circuit board 12 is held by the second V-shaped holding portion 43.

### Second Embodiment

Next, a second embodiment will be described with reference to the drawings.

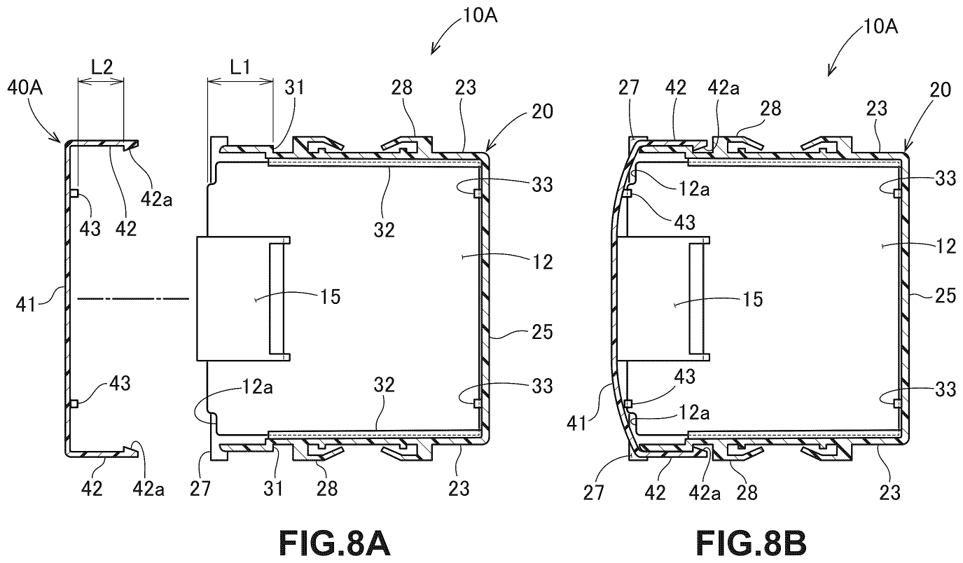

FIGS. 8A and 8B will be used for reference. In an electronic control device 10A according to the second embodiment, the cover 40A is elastically deformed when attached to the case 20. The other basic configurations are common to the electronic control device 10 (see FIG. 3). For configurations common to the electronic control device 10, the same reference numerals will be used and detailed descriptions will be omitted as appropriate.

As shown in FIG. 8A, when the circuit board 12 is inserted into the case 20, the length L1 from the locked portion 31 to the tip of the circuit board 12 is set to be longer than the length L2 from a portion of the locking claw portion 42a coming into contact with the locked portion 31 to a portion of the second V-shaped holding portion 43 coming into contact with the circuit board 12.

FIG. 8B will be used for reference. When attaching the cover 40A to the case 20, the cover 40A is bent and is attached to the case 20 in an elastically deformed state.

### Third Embodiment

Next, a third embodiment will be described with reference to the drawings.

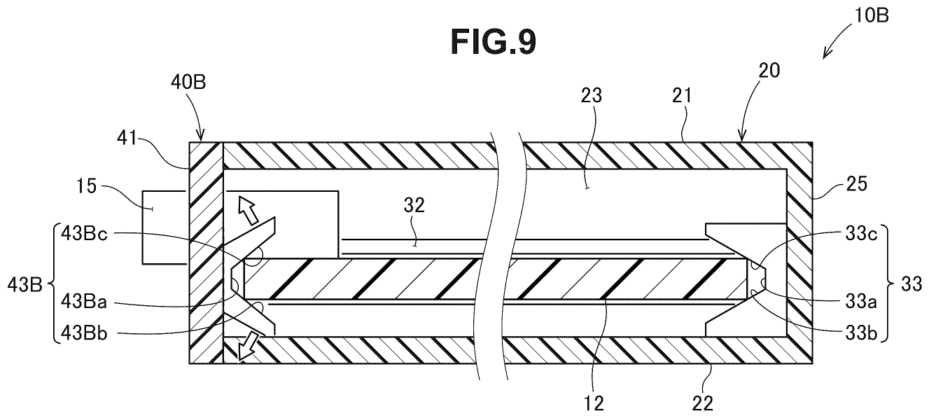

FIG. 9 will be used for reference. An electronic control device 10B according to the third embodiment has a second V-shaped holding portion 43B that is elastically deformable in a direction in which the V shape opens. The other basic configurations are common to the electronic control device 10 (see FIG. 3). For configurations common to the electronic control device 10, the same reference numerals will be used and detailed descriptions will be omitted as appropriate.

A cover 40B that closes the opening of the case 20 has two second V-shaped holding portions 43B which extend toward the edge of the circuit board 12, have a substantially V-shape, and hold the edge of the circuit board 12 from both sides.

Each second V-shaped holding portion 43B is formed at a position facing the first V-shaped holding portion 33. The second V-shaped holding portion 43B has a second bottom portion 43Ba which corresponds to the V-shaped bottom and is thinner than the thickness of the circuit board 12, a second lower tapered portion 43Bb which extends obliquely downward from the lower end of the second bottom portion 43Ba and is elastically deformed downward, and a second upper tapered portion 43Bc which extends obliquely upward from the upper end of the second bottom portion 43a and is elastically deformed upward.

Furthermore, the second lower tapered portion 43Bb and the second upper tapered portion 43Bc may be formed in a curved shape.

The second V-shaped holding portion 43B holds the circuit board 12 in a more open state than the state before the circuit board 12 is held. In a state held by the second V-shaped holding portion 43B, the circuit board 12 is biased in a direction that closes the second V-shaped holding portion 43B. Accordingly, the circuit board 12 is biased toward the first V-shaped holding portion 33.

### Fourth Embodiment

Next, a fourth embodiment will be described with reference to the drawings.

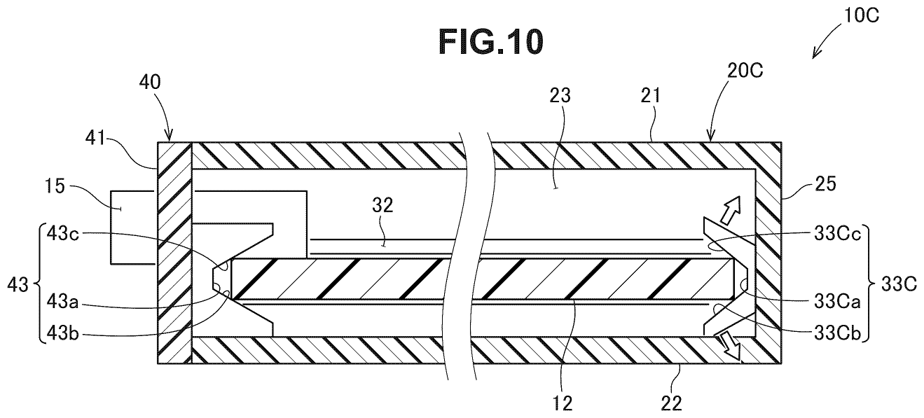

FIG. 10 will be used for reference. An electronic control device 10C according to a fourth embodiment has a first V-shaped holding portion 33C that is elastically deformable in a direction in which the V shape opens. The other basic configurations are common to the electronic control device 10 (see FIG. 3). For configurations common to the electronic control device 10, the same reference numerals will be used and detailed descriptions will be omitted as appropriate.

A case 20C which accommodates the circuit board 12 has two first V-shaped holding portions 33C which extend toward the edge of the circuit board 12, have a substantially V-shape, and hold the edge of the circuit board 12 from both sides.

Each first V-shaped holding portion 33C is formed at a position facing the second V-shaped holding portion 43. The first V-shaped holding portion 33C has a first bottom portion 33Ca which corresponds to the V-shaped bottom and is thinner than the thickness of the circuit board 12, a first lower tapered portion 33Cb which extends obliquely downward from the lower end of the first bottom portion 33Ca, and a first upper tapered portion 33Cc which extends obliquely upward from the upper end of the first bottom portion 33Ca.

Furthermore, the first lower tapered portion 33Cb and the first upper tapered portion 33Cc may be formed in a curved shape.

The first V-shaped holding portion 33C holds the circuit board 12 in a more open state than the state before the circuit board 12 is held. In a state held by the first V-shaped holding portion 33C, the circuit board 12 is biased in a direction that closes the first V-shaped holding portion 33C. Accordingly, the circuit board 12 is biased toward the second V-shaped holding portion 43.

### Fifth Embodiment

Next, a fifth embodiment will be described with reference to the drawings.

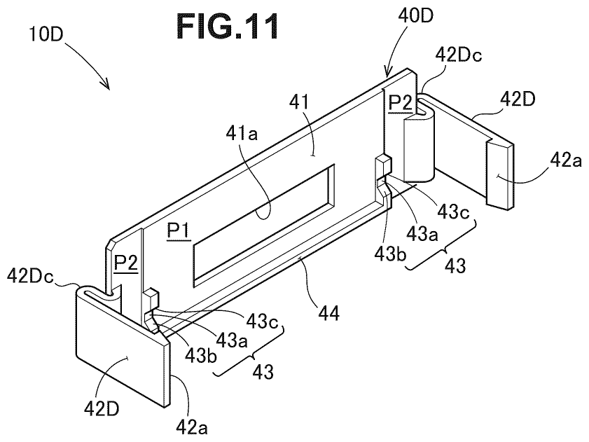

FIG. 11 will be used for reference. In an electronic control device 10D according to the fifth embodiment, an elastic deformation portion 42Dc which is more easily elastically deformable than the other portions is formed in a fixing portion 42D. The other basic configurations are common to the electronic control device 10 (see FIG. 3). For configurations common to the electronic control device 10, the same reference numerals will be used and detailed descriptions will be omitted as appropriate.

In a cover 40D that closes the opening of the case 20 (see FIG. 2), each fixing portion 42D extends along the case 20 from both ends of the cover body 41. The fixing portion 42D is a portion for fixing the cover 40D to the case 20.

The fixing portion 42D has the elastic deformation portion 42Dc which is more easily elastically deformable than the other portions. By forming a portion that is bent in the opposite direction to the insertion direction of the circuit board 12 at the boundary portion with the cover body 41, a portion from this portion to the locking claw portion 42a is formed to be more easily bent than the other portions. It can be said that the base end of the elastic deformation portion 42Dc is formed by bending the boundary portion with the cover body 41 in the opposite direction to the insertion direction of the circuit board 12.

### Sixth Embodiment

Next, a sixth embodiment will be described with reference to the drawings.

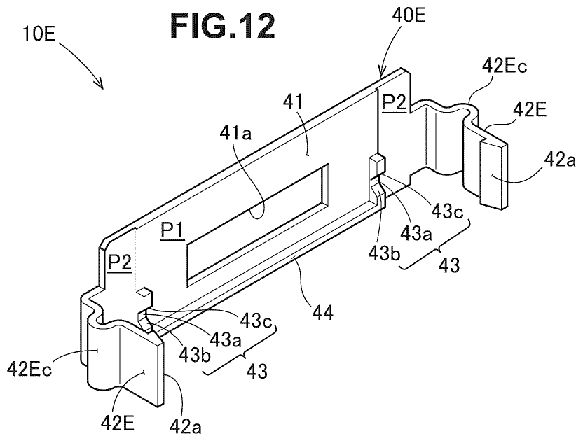

FIG. 12 will be used for reference. In an electronic control device 10E according to the sixth embodiment, an elastic deformation portion 42Ec which is more easily elastically deformable than the other portions is formed in a fixing portion 42E. The other basic configurations are common to the electronic control device 10 (see FIG. 3). For configurations common to the electronic control device 10, the same reference numerals will be used and detailed descriptions will be omitted as appropriate.

In a cover 40E that closes the opening of the case 20 (see FIG. 2), each fixing portion 42E extends along the case 20 from both ends of the cover body 41. The fixing portion 42E is a portion for fixing the cover 40E to the case 20.

The fixing portion 42E has an elastic deformation portion 42Ec which is more easily elastically deformable than the other portions. By forming a portion bent to be away from the case 20 in the fixing portion 42E, a portion from this portion to the locking claw portion 42a is formed to be more easily bent than the other portions. It can be said that the base end of the elastic deformation portion 42Ec is formed by bending a part of the fixing portion 42E away from the case 20.

### Seventh Embodiment

Next, a seventh embodiment will be described with reference to the drawings.

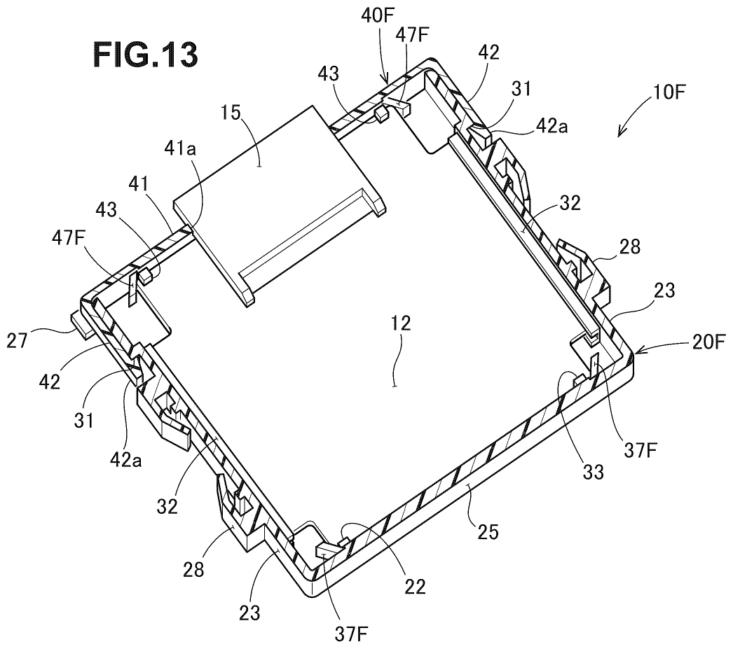

FIG. 13 will be used for reference. In an electronic control device 10F according to the seventh embodiment, the bottom portion 25 of a case 20F is provided with a first left-right direction guide portion 37F which is inclined with respect to the insertion direction of the circuit board 12 and positions the circuit board 12 in a direction perpendicular to the insertion direction. Further, in the electronic control device 10F, a cover 40 is provided with a second left-right direction guide portion 47F which is inclined with respect to the insertion direction of the circuit board 12 and positions the circuit board 12 in a direction perpendicular to the insertion direction.

The other basic configurations are common to the electronic control device 10 (see FIG. 3). For configurations common to the electronic control device 10, the same reference numerals will be used and detailed descriptions will be omitted as appropriate.

The electronic control devices 10 to 10F described above will be summarized below.

FIG. 4 will be used for reference. Firstly, the electronic control device 10 has the case 20 which is open at one end and closed at the other end, the circuit board 12 which is accommodated inside the case 20 and on which electronic components are mountable, and the cover 40 which closes the opening of the case 20. The bottom portion 25 located at the other end of the case 20 is provided with the first V-shaped holding portion 33 which extends toward the edge of the circuit board 12, has a substantially V-shape, and holds the edge of the circuit board 12 from both sides. The cover 40 is provided with the second V-shaped holding portion 43 which extends toward the edge of the circuit board 12, has a substantially V-shape, and holds the edge of the circuit board 12 from both sides. The circuit board 12 is sandwiched between the first V-shaped holding portion 33 and the second V-shaped holding portion 43.

The edge of the circuit board 12 is sandwiched between the first V-shaped holding portion 33 and the second V-shaped holding portion 43 from both sides. Accordingly, the circuit board 12 can be held without rattling. Further, since the area of the contact portion between the first V-shaped holding portion 33 and the circuit board 12 and the area of the contact portion between the second V-shaped holding portion 43 and the circuit board 12 can be small, the area where distortion occurs can be made smaller so that electronic components can be mounted over a wider area. Since a sufficient number of electronic components can be mounted even on a small circuit board 12, a compact electronic control device 10 can be provided.

Further, since the edge of the circuit board 12 is sandwiched between the first V-shaped holding portion 33 and the second V-shaped holding portion 43 from both sides, the circuit board 12 does not need to be bent in order to be held. Therefore, since the load on the circuit board 12 can be reduced, it is possible to contribute to extending the life of the electronic control device 10.

In addition, the case 20, the circuit board 12, and the cover 40 inevitably have dimensional errors for each product. Since the edge of the circuit board 12 is sandwiched between the first V-shaped holding portion 33 and the second V-shaped holding portion 43 from both sides, the edges of the circuit board 12 respectively come into contact with the first V-shaped holding portion 33 and the second V-shaped holding portion 43 at appropriate positions, so that loss of the holding function of the circuit board 12 due to dimensional errors can be prevented. The same applies when each component expands or contracts due to heat.

Furthermore, the electronic control devices 10A, 10B, 10C, 10D, 10E, and 10F also have a similar configuration and provide similar effects.

FIG. 8B will be used for reference. Secondly, in the first electronic control device 10A, the cover 40A is elastically deformed while being attached to the case 20, and biases the circuit board 12 toward the first V-shaped holding portion 33 through the second V-shaped holding portion 43. That is, the circuit board 12 is pressed toward the first V-shaped holding portion 33 by the cover 40A. The circuit board 12 can be held more reliably. Furthermore, this configuration can be also applied to the electronic control devices 10B, 10C, 10D, 10E, and 10F, and when applied, similar effects are achieved.

FIG. 9 will be used for reference. Thirdly, in the first or second electronic control device 10B, the second V-shaped holding portion 43B is elastically deformable in a direction in which the V shape opens. By holding the circuit board 12 while elastically deforming the second V-shaped holding portion 43B, a biasing force is applied to the circuit board 12 in a direction in which the second V-shaped holding portion 43B returns to an original position. The circuit board 12 is pressed toward the first V-shaped holding portion 33 by the force exerted by the second V-shaped holding portion 43B, and is held with higher strength. Furthermore, this configuration can be also applied to the electronic control devices 10C, 10D, 10E, and 10F, and when applied, similar effects are achieved.

FIG. 10 will be used for reference. Fourthly, in any of the first to third electronic control devices 10C, the first V-shaped holding portion 33C is elastically deformable in a direction in which the V shape opens. By holding the circuit board 12 while elastically deforming the first V-shaped holding portion 33C, a biasing force is applied to the circuit board 12 in a direction in which the first V-shaped holding portion 33C returns to an original position. The circuit board 12 is pressed toward the second V-shaped holding portion 43 by the force exerted by the first V-shaped holding portion 33C, and is held with higher strength. Furthermore, this configuration can be also applied to the electronic control devices 10D, 10E, and 10F, and when applied, similar effects are achieved.

FIG. 5 will be used for reference. Fifthly, in any of the first to fourth electronic control devices 10, at least two second V-shaped holding portions 43 are provided, and the plate thickness of the cover 40 is thicker at the portion P1 from the second V-shaped holding portions 43 located at both ends to the second V-shaped holding portion 43 than at the other portions P2. It is possible to suppress the deformation at the portion where the second V-shaped holding portion 43 is formed. Accordingly, each second V-shaped holding portion 43 can be more reliably brought into contact with the circuit board 12, and the circuit board 12 can be held more reliably. Furthermore, this configuration can be also applied to the electronic control devices 10A, 10B, 10C, 10D, 10E, and 10F, and when applied, similar effects are achieved.

FIGS. 11 and 12 will be used for reference. Sixthly, in any of the first to fifth electronic control devices 10D and 10E, the covers 40D and 40E have the cover bodies 41D and 41E which close the opening of the case 20 (see FIG. 2) and the fixing portions 42D and 42E which extend from the cover bodies 41D and 41E along the case 20 and are fixed to the case 20. The fixing portions 42D and 42E are provided with the elastic deformation portions 42Dc and 42Ec which are more easily elastically deformable than the other portions. By allowing elastic deformation over a wider range, it is possible to prevent a load from concentrating on a specific portion. Furthermore, this configuration can be also applied to the electronic control device 10F, and when applied, similar effects are achieved.

FIG. 2 will be used for reference. Seventhly, in any of the first to sixth electronic control devices 10, the bending rigidity of the cover 40 is lower than the bending rigidity of the circuit board 12. That is, the cover 40 is more easily bent than the circuit board 12. The protection of the circuit board 12 can be improved.

Furthermore, although the electronic control device according to the present invention has been described as being mounted on the vehicle, the electronic control device is also applicable to construction machines and the like other than vehicles, and is not limited to these types.

Further, the components shown in each embodiment can be combined as appropriate. At this time, the number of components to be combined may not only be limited to combining one embodiment with one component of another embodiment, but may also be limited to combining one embodiment with components of two or more other embodiments.

Further, the materials constituting the case 20, the circuit board 12, and the cover 40 can be selected arbitrarily from other than those described above, and are not limited to those described in the embodiment.

In other words, the present invention is not limited to the examples as long as the functions and effects of the present invention are achieved.

### INDUSTRIAL APPLICABILITY

The electronic control device of the present invention is suitable for controlling electric components of the vehicle.

### EXPLANATIONS OF LETTERS OR NUMERALS

10, 10A, 10B, 10C, 10D, 10E, 10F ELECTRONIC CONTROL DEVICE
12 CIRCUIT BOARD
20, 20C, 20F CASE
25 BOTTOM PORTION
33, 33C FIRST V-SHAPED HOLDING PORTION
40, 40A, 40B, 40D, 40E, 40F COVER
41 COVER BODY
42 FIXING PORTION
42Dc, 42Ec ELASTIC DEFORMATION PORTION
43,43B SECOND V-SHAPED HOLDING PORTION

1. An electronic control device comprising:
a case which is open at one end and closed at the other end;
a circuit board which is accommodated inside the case and on which electronic components are mountable; and
a cover which closes an opening of the case,
wherein a bottom portion located at the other end of the case is provided with a first V-shaped holding portion which extends toward an edge of the circuit board, has a substantially V-shape, and holds the edge of the circuit board from both sides,
wherein the cover is provided with a second V-shaped holding portion which extends toward the edge of the circuit board, has a substantially V-shape, and holds the edge of the circuit board from both sides, and
wherein the circuit board is sandwiched between the first V-shaped holding portion and the second V-shaped holding portion.

2. The electronic control device according to claim 1,
wherein the cover is elastically deformable while being mounted on the case, and biases the circuit board toward the first V-shaped holding portion through the second V-shaped holding portion.

3. The electronic control device according to claim 1,
wherein the second V-shaped holding portion is elastically deformable in a direction in which the V shape opens.

4. The electronic control device according to claim 1,
wherein the first V-shaped holding portion is elastically deformable in a direction in which the V shape opens.

5. The electronic control device according to claim 1,
wherein at least two second V-shaped holding portions are provided, and
wherein a plate thickness of the cover is thicker in a portion from the second V-shaped holding portions located at both ends to the second V-shaped holding portion than the other portions.

6. The electronic control device according to claim 1,
wherein the cover has a cover body which closes the opening of the case and a fixing portion which extends from the cover body along the case and is fixed to the case, and
wherein the fixing portion is provided with an elastic deformation portion which is more easily elastically deformable than the other portions.

7. The electronic control device according to claim 1,
wherein the cover has a bending rigidity lower than a bending rigidity of the circuit board.
